(19) United States
(12) Patent Application Publication
(10) Pub. No.: US 2012/0132461 A1
(43) Pub. Date: May 31, 2012

(54) PRINTED CIRCUIT BOARD

(75) Inventor: TSUNG-SHENG HUANG, Tu-Cheng (TW)

(73) Assignee: HON HAI PRECISION INDUSTRY CO., LTD., Tu-Cheng (TW)

(21) Appl. No.: 12/981,477

(22) Filed: Dec. 30, 2010

(30) Foreign Application Priority Data
Nov. 29, 2010 (TW) 99141306

(51) Int. Cl. H05K 1/16

(52) U.S. Cl. 174/260

(57) ABSTRACT

A printed circuit board includes a top layer and a bottom layer. A power supply and an electronic component are located on the top layer. The power supply is connected to the top layer and the bottom layer through a first via. A number of second vias extend through the printed circuit board and are connected to the top layer and the bottom layer. The distance between each second via and the electronic component is the same.

### BACKGROUND

1. Technical Field

The present disclosure relates to a printed circuit board (PCB).

2. Description of Related Art

Referring to FIGS. 3 and 4, a conventional PCB includes a top layer 1, a bottom layer 2, a signal layer 3, and a ground layer 4. The top layer 1 and the bottom layer 2 are the power layers. An electronic component 5 is located on the top layer 1. Vias, such as 6a, 6b, 7a, and 7b are defined through the PCB, and are connected to the top layer 1 and the bottom layer 2. A power supply 8 located on the top layer 1 is connected to the top layer 1 and the bottom layer 2 through two vias 8a and 8b, to supply power to the electronic component 5. A part of the current of the power supply 8 flows to the electronic component 5 through the top layer 1. Another part of the current of the power supply 8 flows to the bottom layer 2 through the vias 8a, 8b, 9a, and 9b at first, then returns to the top layer 1 through the vias 6a, 6b, 7a, and 7b, and then flows to the electronic component 5 through the top layer 1. Because the current would flow to the electronic component 5 through a path with the least resistance, the current on the bottom layer 2 would flow to the top layer 1 through the via 7b which is the closest via to the electronic component 5. As a result, if the current passing through the via 7b is too high, the resulting high temperature created may make the PCB unstable or may even damage the PCB.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of an exemplary embodiment of a printed circuit board.

FIG. 2 is a sectional view of the printed circuit board of FIG. 1, taken along the line II-II.

FIG. 3 is a schematic diagram of a conventional printed circuit board.

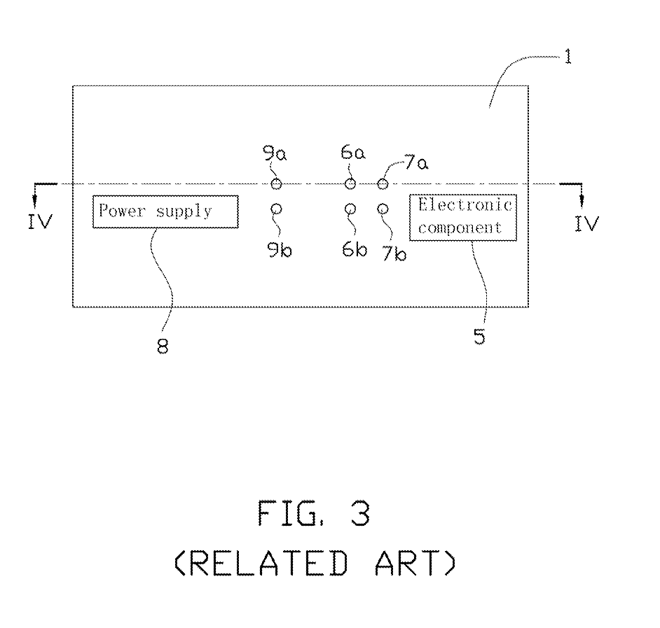

FIG. 4 is a sectional view of the printed circuit board of FIG. 3, taken along the line IV-IV.

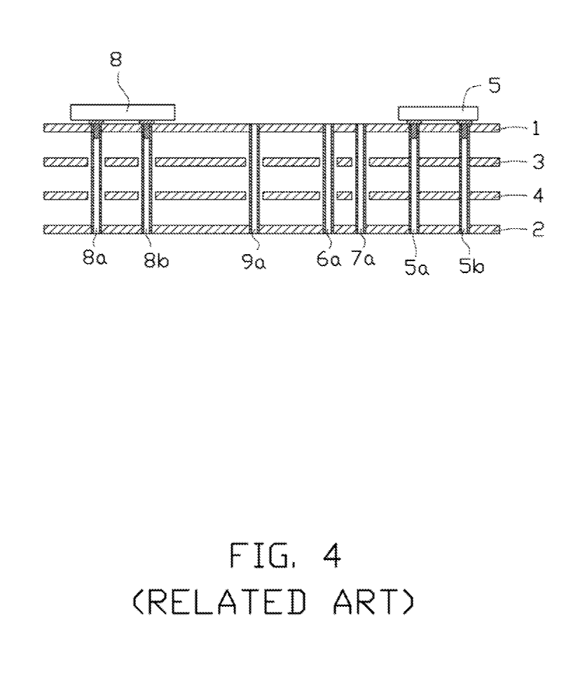

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

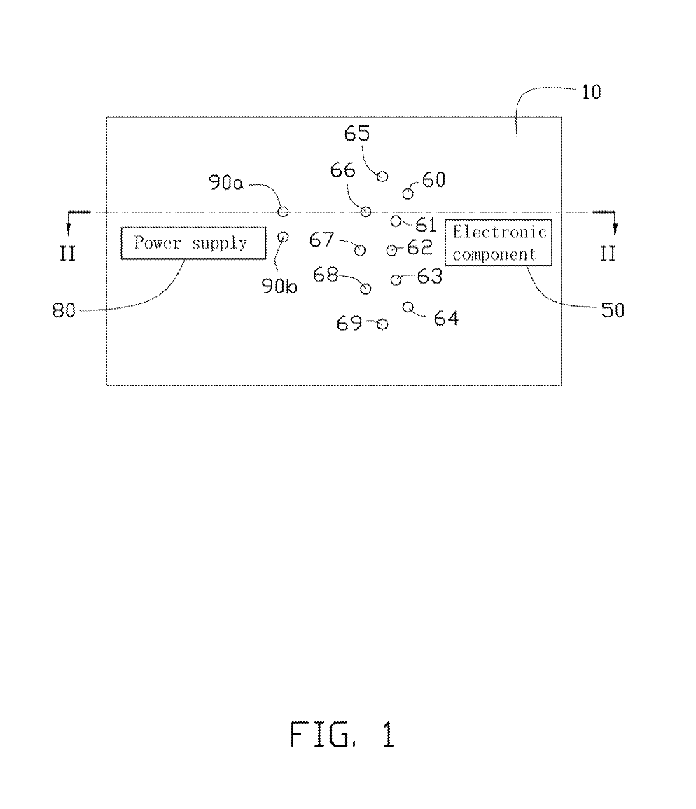

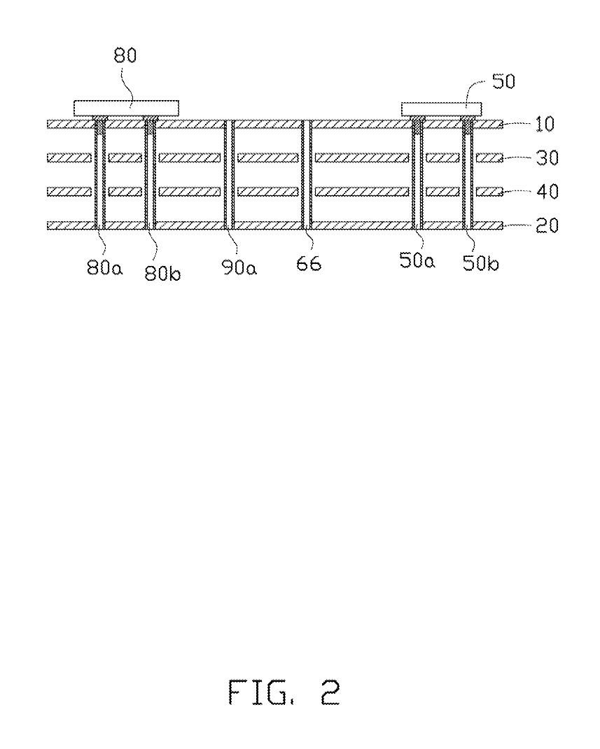

Referring to FIGS. 1 and 2, an exemplary embodiment of a printed circuit board (PCB) includes a top layer 10, a bottom layer 20, a ground layer 30, and a signal layer 40. The top layer 10 and the bottom layer 20 are power layers. An electronic component 50 is located on the top layer 10. A plurality of vias extends through the PCB and is connected to the top layer 10 and the bottom layer 20. In the embodiment, the plurality of vias include ten vias 60-69.

A power supply 80 located on the top layer 10 is connected to the top layer 10 and the bottom layer 20 through two vias 80a and 80b, to supply power to the electronic component 50. A part of the current from the power supply 80 flows to the electronic component 50 through the top layer 10. Another part of the current of the power supply 80 flows to the bottom layer 20 through the vias 80a, 80b, 90a, and 90b at first, then returns to the top layer 10 through the vias 60-69, and then flows to the electronic component 50 through the top layer 10.

The vias 60-69 are arranged in two rows. Each row of vias are arranged in a sector whose center coincides with the electronic component 50. As a result, distances between the vias 60-64 in the first row and the electronic component 50 are the same, and distances between the vias 65-69 in the second row and the electronic component 50 are the same.

Because the current on the bottom layer 20 flows to the electronic component 50 through a path with the least resistance, the current on the bottom layer 2 flows to the top layer 1 through the vias 60-64 which are the closest vias to the electronic component 50. A current at each vias 60-64 in the first row is obtained as table 1:

TABLE 1

| | | | | | |
|---|---|---|---|---|---|
| Vias in the first Row | 60 | 61 | 62 | 63 | 64 |
| Current(A) | 4.007 | 3.305 | 3.099 | 3.033 | 3.234 |
| Vias in the second Row | 65 | 66 | 67 | 68 | 69 |
| Current(A) | 2.619 | 1.939 | 1.701 | 1.662 | 1.809 |

As a result, the current passes through each of the vias 60-64 in the first row is almost the same, thus avoiding a greater current at one of the vias.

In other embodiments, the vias 60-64 in the first row may be arranged in other shapes. As long as the distance between each of the vias 60-64 in the first row and the electronic component 50 is the same.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board comprising a top layer and a bottom layer, wherein a power supply and an electronic component are located on the top layer, the power supply is connected to the top layer and the bottom layer through at least one first via, a plurality of second vias extend through the printed circuit board and are connected to the top layer and the bottom layer, distances between the plurality of second vias and the electronic component are the same.

2. The printed circuit board of claim 1, wherein the plurality of second vias are arranged in a sector.

3. The printed circuit board of claim 2, wherein a center of the sector coincides with the electronic component.
